(19) United States
(12) Patent Application Publication
(10) Pub. No.: US 2026/0190291 A1
(43) Pub. Date: Jul. 2, 2026

(54) FLEXIBLE VAPOR CHAMBER

(71) Applicant: FORCECON TECHNOLOGY CO., LTD., Zhubei City (TW)

(72) Inventors: DONG-YUAN TSAI, Zhubei City (TW); SHAO-NAN CHEN, Zhubei City (TW); CHI-YU CHANG, Zhubei City (TW); MING-TSUNG HUNG, Zhubei City (TW); MING-CHIH CHEN, Zhubei City (TW); CHEN-CHI JAO, Zhubei City (TW)

(21) Appl. No.: 19/006,225

(22) Filed: Dec. 31, 2024

(51) Int. Cl. H05K 7/20

(52) U.S. Cl. CPC H05K 7/20336; H05K 7/20327

(57) ABSTRACT

A flexible vapor chamber comprises two casings and a wick structure. The casings are joined to form a perimeter seal that encloses a chamber between the casings. The chamber contains a working fluid configured to absorb and release thermal energy. Each casing includes a bendable zone positioned between two rigid sections. The chamber is primarily formed by a first space connecting two second spaces. The wick structure, positioned in the chamber, comprises multiple elongated first capillary members positioned within the first space and extending into the second spaces. Each first capillary member is spirally wound in the second and third directions, providing enhanced bending resistance while maintaining flexibility.

### FIELD OF INVENTION

The present invention relates to a heat dissipation device and more particularly to a flexible vapor chamber.

### BACKGROUND OF THE INVENTION

A vapor chamber is a type of heat dissipation device commonly used in electronic equipment. It typically consists of a base plate and a cover plate joined together to form an internal chamber. This chamber contains a working fluid and a wick structure. The working fluid facilitates the absorption and release of thermal energy, while the wick structure guides the flow of the working fluid.

The wick structure is generally composed of copper wires or a copper mesh formed by multiple interwoven copper wires. It directs the flow of the working fluid, enabling phase changes to occur as the fluid absorbs and releases heat. This mechanism allows the vapor chamber to efficiently absorb and rapidly dissipate significant amounts of thermal energy, resulting in a uniform temperature throughout the device.

A known flexible vapor chamber, specifically designed for use in foldable electronic devices, is capable of being bent repeatedly to accommodate the folding operations of the device. However, the copper wires in the wick structure, which are subjected to continuous bending, are susceptible to fatigue and eventual breakage, compromising the performance and reliability of the vapor chamber.

### SUMMARY OF THE INVENTION

The main purpose of the present invention is to provide a flexible vapor chamber. In order to achieve the aforementioned purpose, the present invention employs the following technical solution:

A flexible vapor chamber, comprising two casings and a wick structure, wherein each casing is a plate-like structure having a width, a length, and a thickness, with the length direction defined as a first direction, the width direction defined as a second direction, and the thickness direction defined as a third direction;
the two casings face each other along the third direction and are joined to form a perimeter seal that encloses a chamber between the casings and the perimeter seal; the chamber contains a working fluid configured to absorb and release thermal energy, wherein one of the casings is configured with multiple support pillars extending into the chamber and connecting to the opposite casing;
each casing also comprises a bendable zone and two rigid sections extending along the first direction, with the bendable zone positioned between the two rigid sections and extending to both opposite sides of the casing along the second direction, thereby enabling the casing to flex and bend along the third direction;
the chamber is primarily formed by a first space connecting two second spaces, the first space being located between the second spaces and aligned with the bendable zones in the third direction, while each second space is located between the two rigid sections in the third direction;
the wick structure is positioned in the chamber and comprises multiple elongated first capillary members, wherein each first capillary member is spaced apart along the second direction, positioned within the first space, wound into a spiral shape along the second direction and the third direction, and extends axially along the first direction into each second space, thereby directing the working fluid to flow between the second spaces through the first space along the first direction.

The present invention further provides a flexible vapor chamber in which each first capillary member can be selectively replaced with multiple strands. Each of these strands is spirally wound in the second and third directions.

By accommodating the bending requirements of the bendable zone, each first capillary member exhibits enhanced bending resistance in the second and third directions. This design minimizes the likelihood of fatigue and breakage in the first capillary members, thereby achieving a balance between the flexibility required for bending and improved bending resistance.

### BRIEF DESCRIPTION OF THE DRAWINGS

FIG. 1 is a perspective view of the first embodiment of the present invention;

FIG. 2 is an exploded perspective view of the first embodiment of the present invention;

FIG. 3 is a sectional view cut along the length direction of the first embodiment of the present invention;

FIG. 4 is a partially enlarged view of FIG. 3;

FIG. 5 is a sectional view along line 5-5 of FIG. 3, showing a top view of the wick structure;

FIG. 6 is a partially enlarged view of FIG. 5;

FIG. 7 is a partial perspective view of the first capillary member of the first embodiment of the present invention;

FIG. 8 is a partial perspective view of the first capillary member of the second embodiment of the present invention;

FIG. 9 is a radial cross-sectional view of the first capillary member of the third embodiment of the present invention;

FIG. 10 is a radial cross-sectional view of the first capillary member of the fourth embodiment of the present invention;

FIG. 11 is a radial cross-sectional view of the first capillary member of the fifth embodiment of the present invention;

FIG. 12 is a partial perspective view of the first capillary member of the sixth embodiment of the present invention;

FIG. 13 is a partial perspective view of the first capillary member of the seventh embodiment of the present invention;

FIG. 14 is a partial perspective view of the first capillary member of the eighth embodiment of the present invention;

FIG. 15 is a partial perspective view of the first capillary member of the ninth embodiment of the present invention;

FIG. 16 is a top view of the first capillary member of the tenth embodiment of the present invention;

FIG. 17 is a partial perspective view of the first capillary member of the eleventh embodiment of the present invention;

FIG. 18 is a sectional view of the twelfth embodiment of the present invention, showing a top view of the wick structure;

FIG. 19 is a sectional view of the thirteenth embodiment of the present invention, showing a top view of the wick structure;

FIG. 20 is a sectional view of the fourteenth embodiment of the present invention, showing a top view of the wick structure;

FIG. 21 is a sectional view of the fifteenth embodiment of the present invention, showing a top view of the wick structure;

FIG. 22 is a partial sectional view of the sixteenth embodiment of the present invention;

FIG. 23 is a partial side view of the seventeenth embodiment of the present invention; and

FIG. 24 is a partial side view of the eighteenth embodiment of the present invention.

### DETAILED DESCRIPTION OF THE PREFERRED EMBODIMENTS

The accompanying drawings show embodiments of the flexible vapor chamber of the present invention. These embodiments are provided for illustrative purposes only and should not be construed as limiting the scope of the patent application.

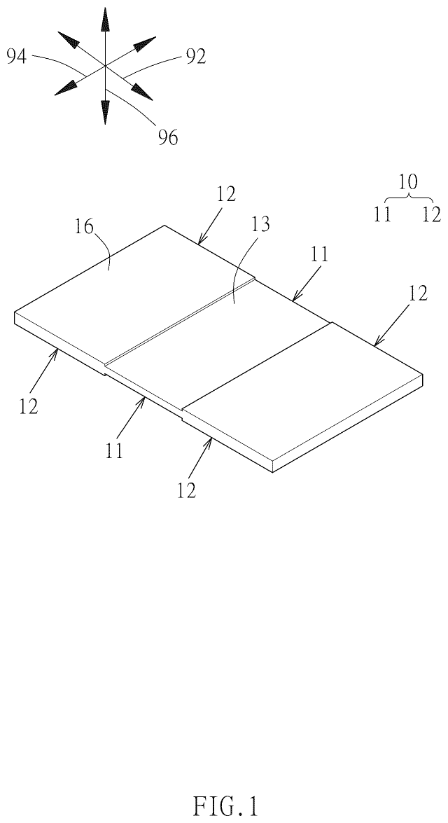

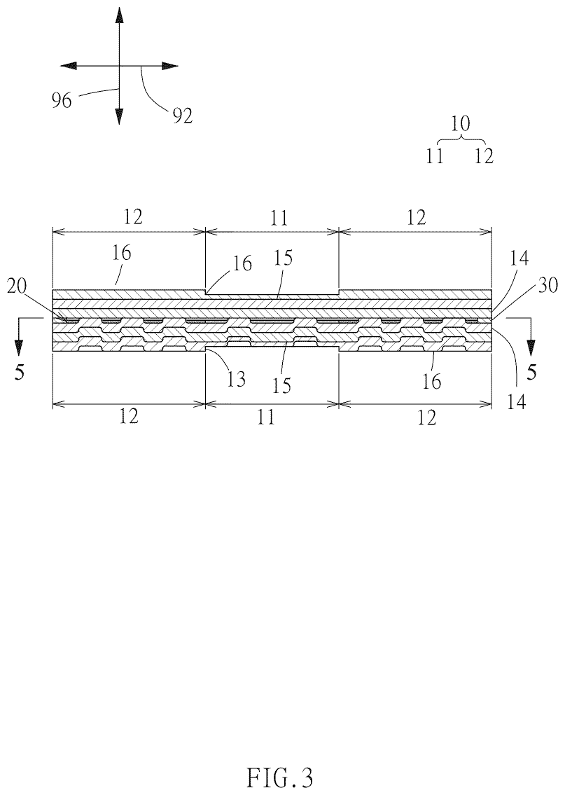

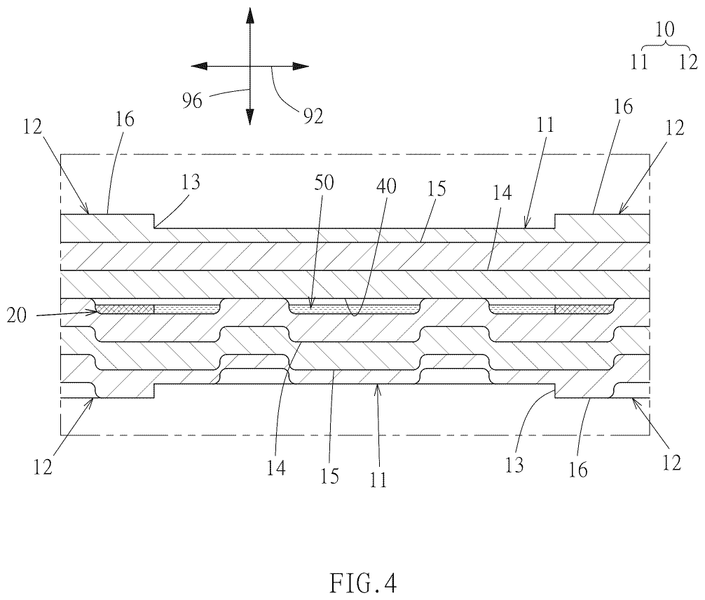

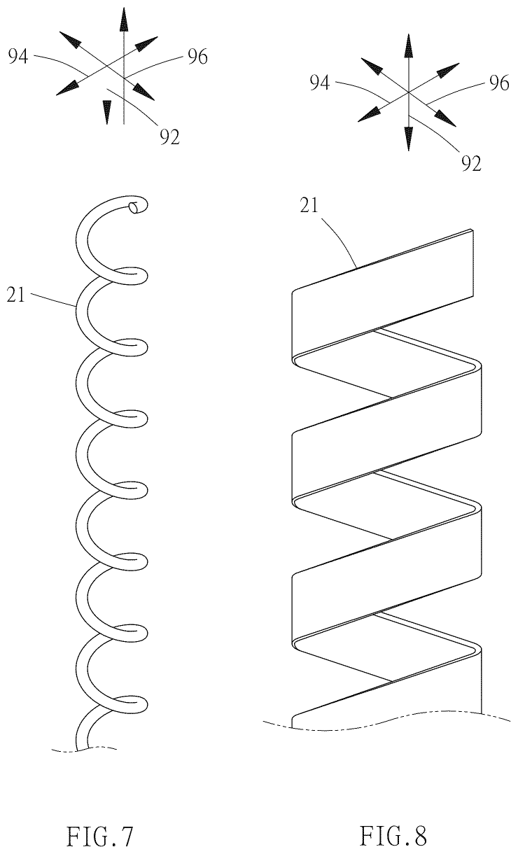

As shown in FIGS. 1 to 7, a first embodiment of the flexible vapor chamber comprises two casings 10 and a wick structure 20. Each casing 10 is a plate-like structure defined by its width and length. The length of each casing 10 is referred to as a first direction 92, the width as a second direction 94, and the thickness as the third direction 96. The two casings 10 face each other along the third direction 96 and are joined to form a perimeter seal 30, which encloses a chamber 40 between the casings 10 and the perimeter seal 30. The chamber 40 contains a working fluid 50 which facilitates the absorption and release of thermal energy. One of the casings 10 is configured with multiple support pillars 60 that extend into the chamber 40 and connect to the opposite casing 10. Each casing 10 also comprises a bendable zone 11 and two rigid sections 12 along the first direction 92. The bendable zone 11 is positioned between the two rigid sections 12 of each casing 10 and extends across the second direction 94 to both sides of the casing 10. This design enables each casing 10 to flex and bend along the third direction 96.

Specifically, each casing 10 forms a thinned recess 13 on the side opposite the chamber 40 in the third direction 96, causing each casing 10 to have a reduced thickness forming each bendable zone 11. The thickness of each bendable zone 11 is less than the thickness of the rigid sections 12 to which it connects.

Each casing 10 is primarily composed of a layered structure consisting of a first metallic layer 14, a flexible polymer membrane 15, and a second metallic layer 16. Each polymer membrane 15 is sandwiched between the first metallic layer 14 and the second metallic layer 16. Each first metallic layer 14 is located on the side of each casing 10 facing the chamber 40 in the third direction 96. Each second metallic layer 16 is located on the side of each casing 10 opposite the chamber 40 in the third direction 96. Each thinned recess 13 is formed on each second metallic layer 16.

The chamber 40 is primarily formed by a first space 42 connecting two second spaces 44. The first space 42 is located between the second spaces 44 and aligns with the bendable zones 11 in the third direction 96, while each second space 44 is located between the two rigid sections 12 in the third direction 96.

The wick structure 20 is positioned in the chamber 40 to direct the flow of the working fluid 50. As the working fluid 50 absorbs and releases heat, it undergoes a phase change which allows it to efficiently absorb large amounts of thermal energy and rapidly dissipate it to achieve a uniform temperature.

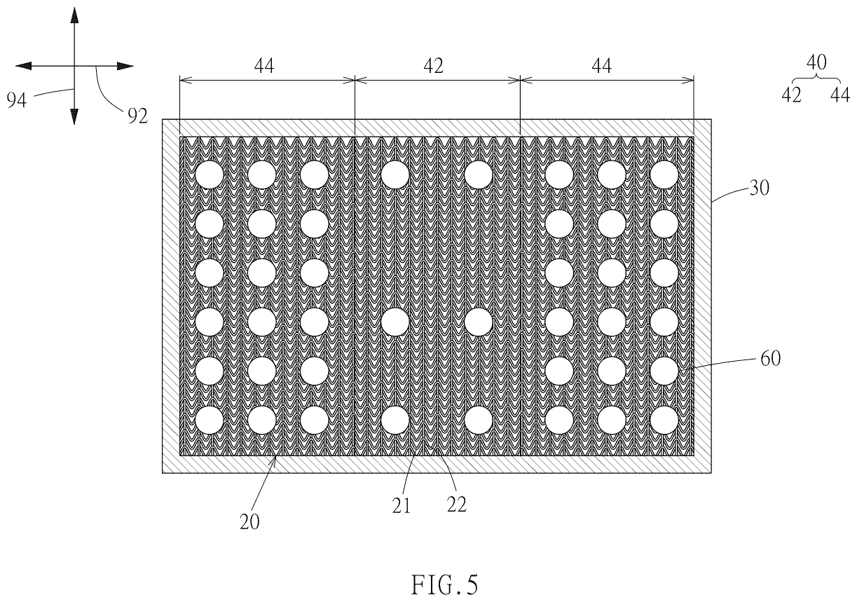

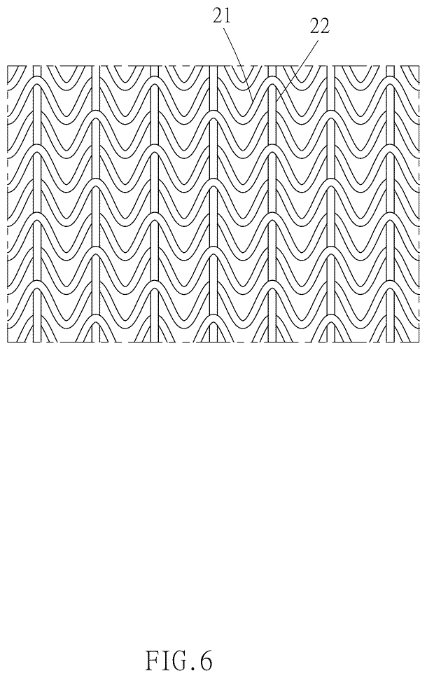

In order to clearly illustrate the wick structure 20, the working fluid 50 is not shown in FIGS. 5 and 6. The wick structure 20 comprises multiple elongated first capillary members 21. Each first capillary member 21 is spaced apart along the second direction 94 and positioned within the first space 42. Each first capillary member 21 is wound into a spiral shape in the second direction 94 and third direction 96, with its axis extending along the first direction 92 into each second space 44. This configuration directs the working fluid 50 to flow between the second spaces 44 through the first space 42 along the first direction 92.

Each first capillary member 21 is spirally wound in the second direction 94 and the third direction 96. This design ensures that each first capillary member 21 accommodates the bending requirements of the bendable zone 11 while providing enhanced bending resistance in the second direction 94 and the third direction 96. Compared to the copper wires used in the prior art, the first capillary member 21 is less susceptible to fatigue and breakage, thus meeting the dual requirements of flexibility for bending and improved bending resistance.

In the first embodiment, spiral strands made of metal or fiber material with a circular radial cross-section are selected as each first capillary member 21.

The wick structure 20 further includes multiple transverse wicks 22. Each transverse wick 22 extends along the second direction 94 and is spaced apart along the first direction 92. Each transverse wick 22 intersects with each first capillary member 21 in the third direction 96, forming an interwoven structure that creates a mesh configuration for the wick structure 20.

As shown in FIG. 8, the second embodiment differs from the first embodiment in that the radial cross-section of each first capillary member 21 is rectangular.

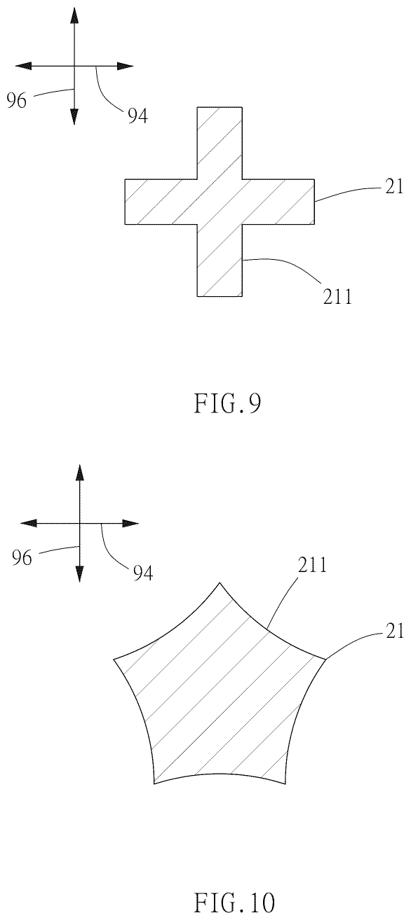

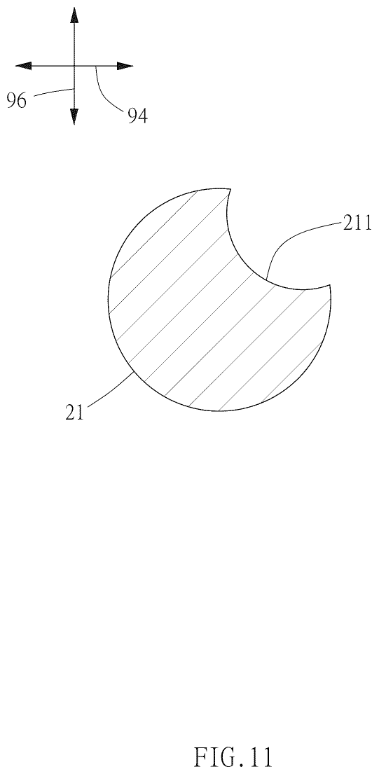

As shown in FIGS. 9, 10, and 11, the third, fourth, and fifth embodiments differ from the first embodiment in that each first capillary member 21 has an axial groove 211 formed by an indentation along its radial periphery. Each axial groove 211 extends along the axis of the first capillary member 21 to both ends, enabling the working fluid 50 to flow into each axial groove 211.

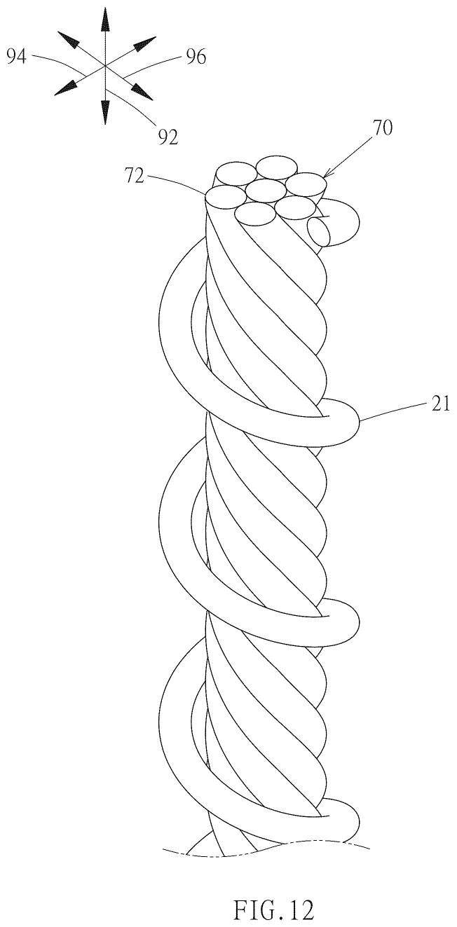

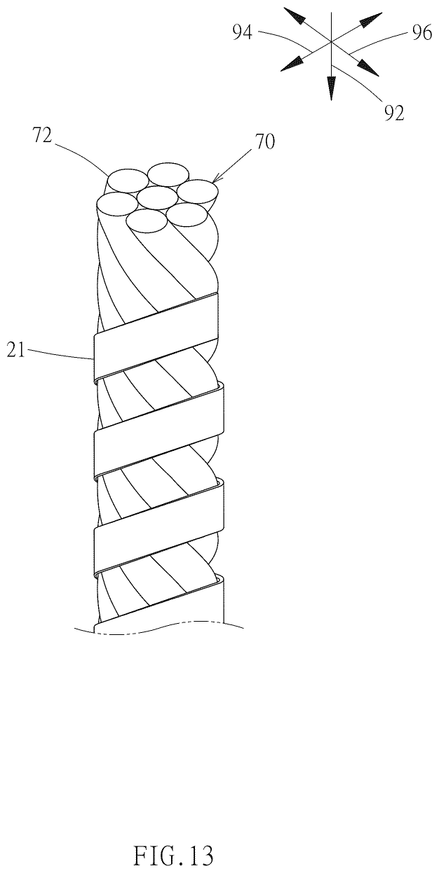

As shown in FIGS. 12 and 13, the sixth and seventh embodiments differ from the first embodiment in that they further include multiple bundles 70. Each bundle 70 is formed by twisting multiple textile fibers 72, wherein the axis of each bundle 70 extends along the first direction 92, and each first capillary member 21 is wound around a bundle 70. Specifically, each textile fiber 72 is made of yarn.

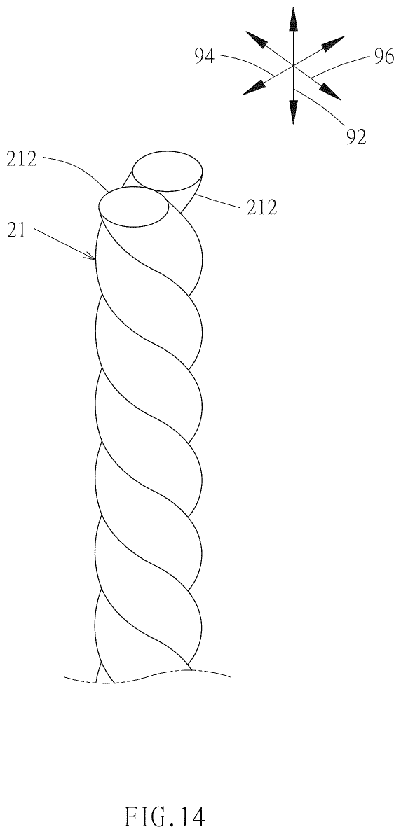

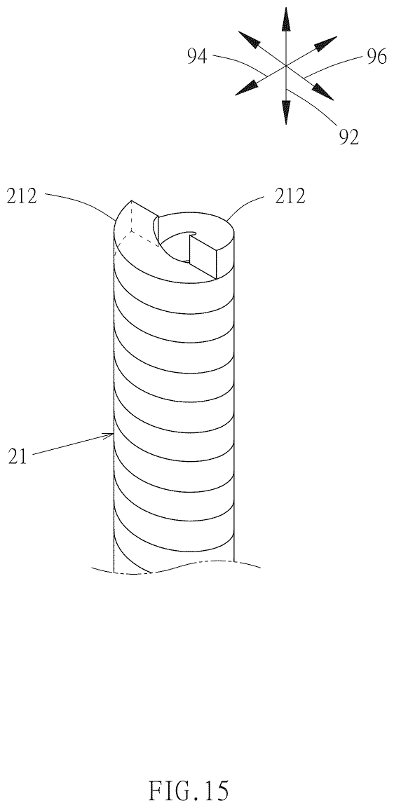

As shown in FIGS. 14 and 15, the eighth and ninth embodiments differ from the first embodiment in that each first capillary member 21 is formed primarily by twisting two strands 212. Each strand 212 is wound into a spiral shape in the second direction 94 and the third direction 96. This configuration enables each first capillary member 21 in the eighth and ninth embodiments to meet the requirements for conforming to the bending of the bendable zone 11, while providing enhanced bending resistance in the second direction 94 and the third direction 96. In addition, this design significantly reduces the likelihood of fatigue and breakage and achieves the dual requirements of flexibility and bending resistance. The eighth and ninth embodiments demonstrate the first capillary members 21 composed of the multiple strands 212, which exhibit superior bending resistance compared to the spiral strands used in the first embodiment.

The main difference between the eighth and ninth embodiments lies in the radial cross-section of the strands 212. The eighth embodiment uses the strands 212 with circular radial cross-sections to form each first capillary member 21, while the ninth embodiment uses strands 212 with rectangular radial cross-sections.

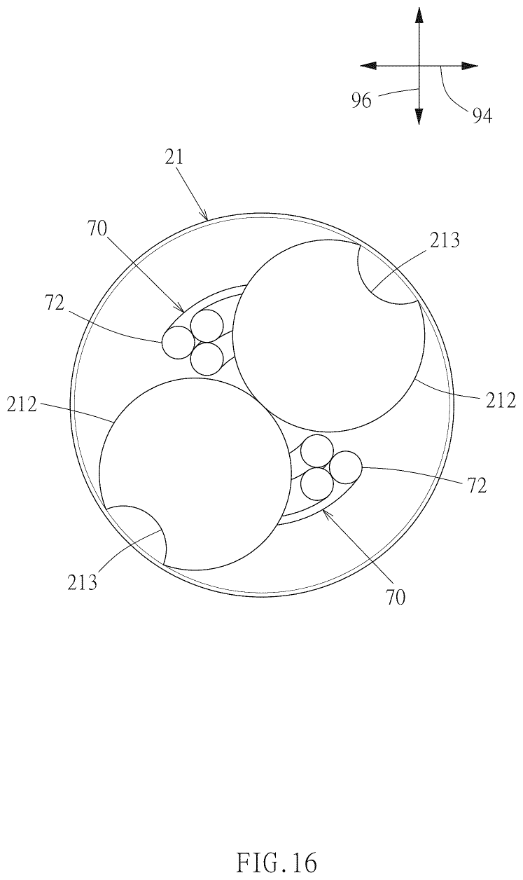

As shown in FIG. 16, the tenth embodiment differs from the eighth embodiment in that each strand 212 has a strand groove 213 formed by an indentation along its radial periphery. Each strand groove 213 extends to both ends of each strand 212 along its axis, allowing the working fluid 50 to flow into the strand groove 213.

The tenth embodiment also includes the multiple bundles 70 as shown in the sixth embodiment. Each bundle 70 is formed by twisting the multiple textile fibers 72, with the axis of each bundle 70 extending along the first direction 92. Specifically, each textile fiber 72 is made of yarn. In this embodiment, the multiple strands 212 and the bundles 70 are twisted together to form each first capillary member 21.

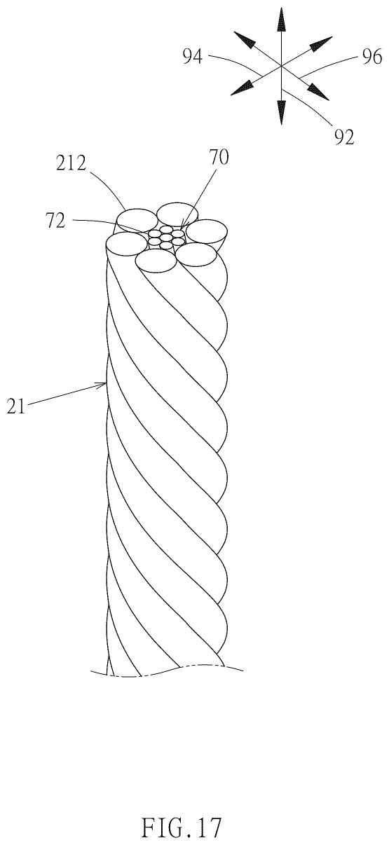

As shown in FIG. 17, the eleventh embodiment differs from the eighth embodiment in that each first capillary member 21 is formed by twisting the multiple strands 212, with each strand 212 wound into a spiral shape in the second direction 94 and the third direction 96. Furthermore, the eleventh embodiment includes the multiple bundles 70, as shown in the sixth embodiment. Each bundle 70 is formed by twisting the multiple textile fibers 72, and the multiple strands 212 are wound around each bundle 70 to form each first capillary member 21.

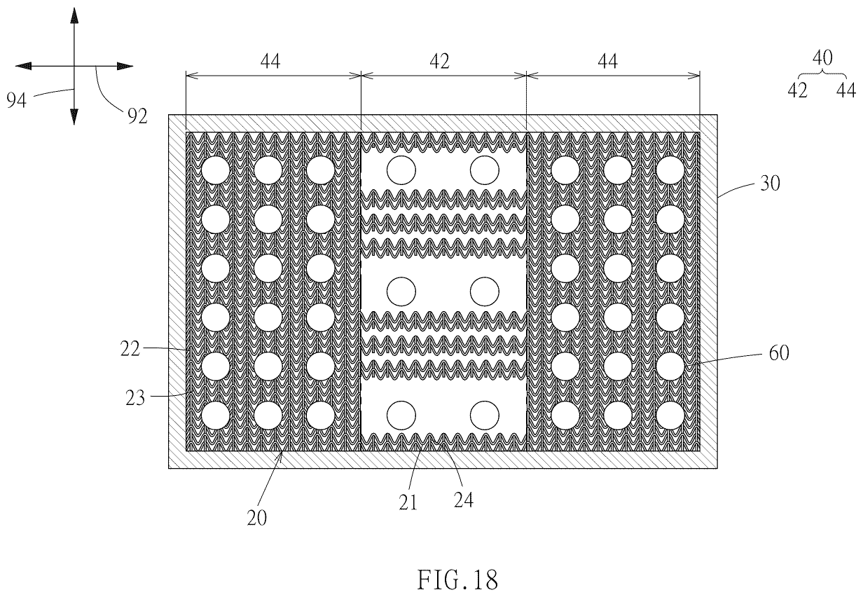

As shown in FIG. 18, the twelfth embodiment differs from the first embodiment in that the wick structure 20 additionally includes multiple second capillary members 23 and intermediate wicks 24. Each transverse wick 22 and each second capillary member 23 is positioned in each second space 44, with each second space 44 containing multiple of the transverse wicks 22 and second capillary members 23. Each second capillary member 23 is spirally wound in the second direction 94 and the third direction 96, with its axis extending along the first direction 92. This configuration allows each second capillary member 23 to guide the working fluid 50 to flow between the first space 42 and the corresponding second space 44 along the first direction 92.

Each second capillary member 23 is located between two first capillary members 21 and is spaced apart from two adjacent first capillary members 21 along the second direction 94. Each transverse wick 22 intersects with the first capillary members 21 and the second capillary members 23 in the third direction 96, forming an interwoven structure. The intermediate wicks 24 are arranged in an array pattern within the first space 42, each intermediate wick 24 extending along the second direction 94 and intersecting with two adjacent first capillary members 21 in the second direction 94 and the third direction 96, and creating an interwoven structure.

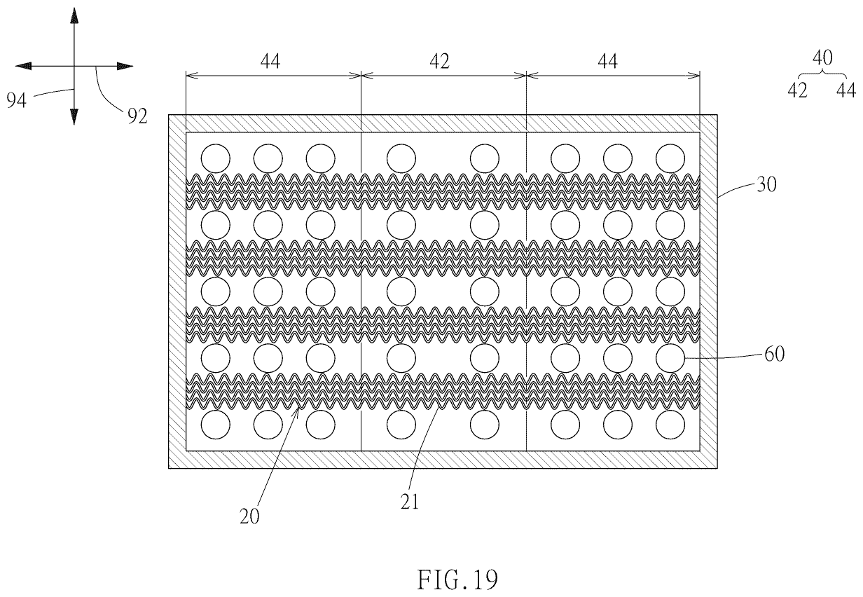

As shown in FIG. 19, the thirteenth embodiment differs from the first embodiment in that the multiple first capillary members 21 are bundled together and positioned adjacent to each other along the second direction 94. In addition, the thirteenth embodiment omits the transverse wicks 22 included in the first embodiment.

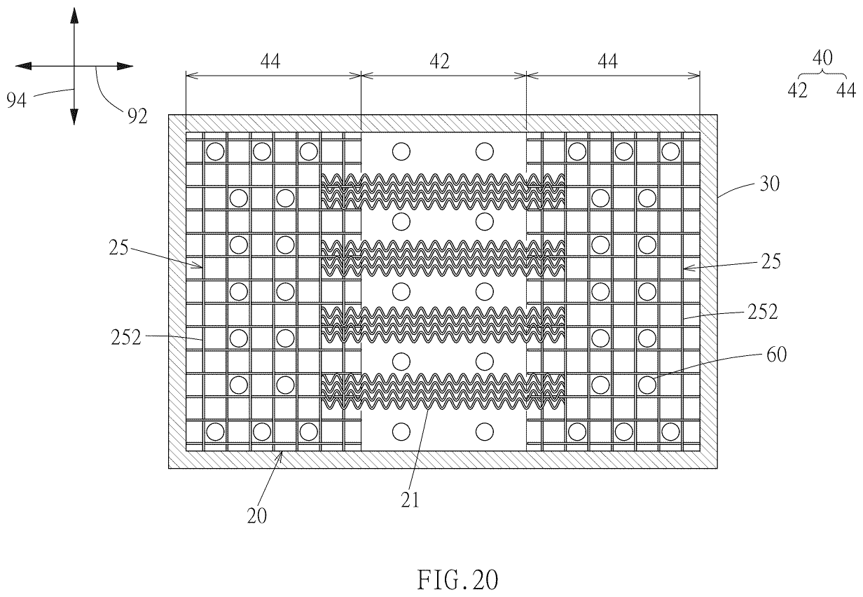

As shown in FIG. 20, the fourteenth embodiment differs from the thirteenth embodiment in that each first capillary member 21 extends from the first space 42 into a portion of each second space 44. In addition, the wick structure 20 further includes two wicking grids 25, each located within a respective second space 44. Each wicking grid 25 is formed by multiple intersecting and interwoven grid wicks 252, with each first capillary member 21 connecting to the corresponding wicking grid 25.

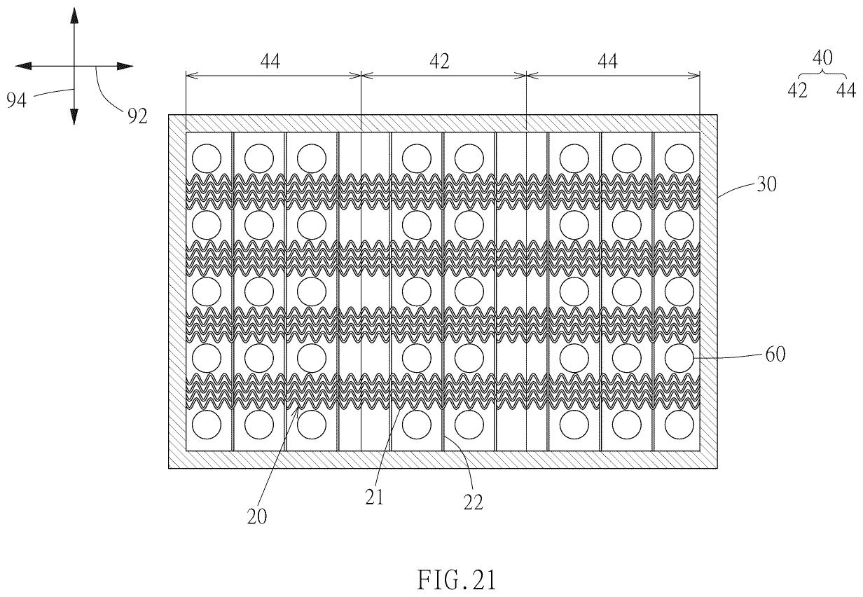

As shown in FIG. 21, the fifteenth embodiment differs from the thirteenth embodiment in that the wick structure 20 includes the multiple transverse wicks 22, as shown in the first embodiment. Each transverse wick 22 extends along the second direction 94 and is spaced apart along the first direction 92. Each transverse wick 22 intersects with each first capillary member 21 in the third direction 96, forming an interwoven structure.

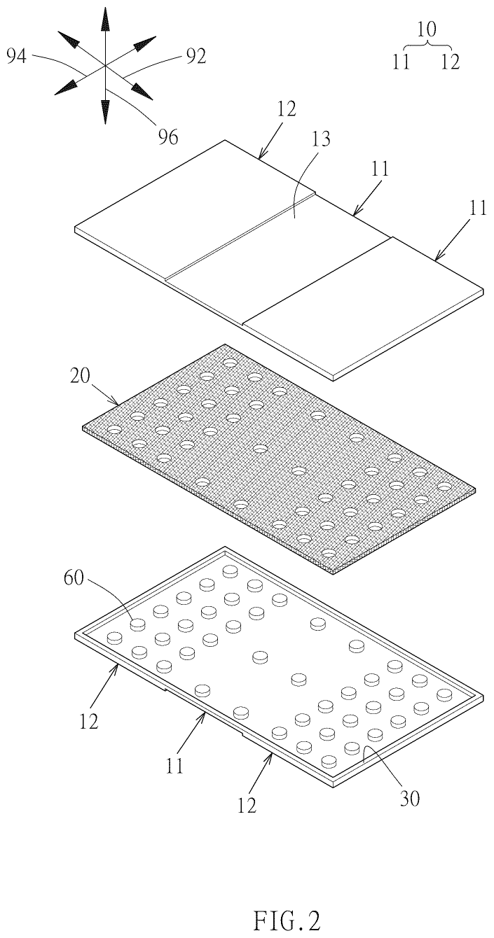

In order to clearly illustrate the wick structure 20, the working fluid 50 is not shown in FIGS. 2, 5, 6, 18, and 21.

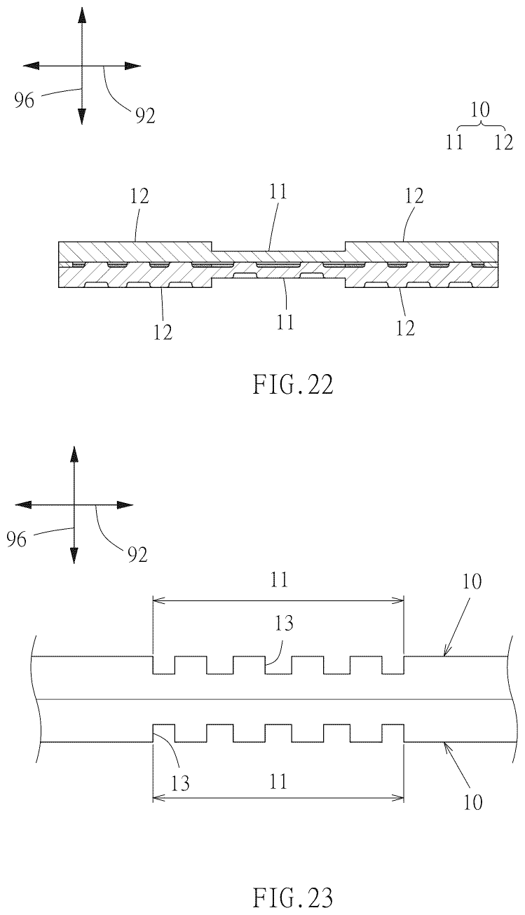

As shown in FIG. 22, the sixteenth embodiment differs from the first embodiment in that each casing 10 is integrally formed from a metal material.

The first capillary members 21 of the twelfth to fifteenth embodiments can each be replaced with the first capillary members 21 mainly formed by twisting the multiple strands 212, as shown in the eighth, ninth, tenth, or eleventh embodiment. Similarly, the second capillary members 23 of the twelfth embodiment can each be replaced with a structure mainly formed by twisting the multiple strands 212, as shown in the eighth, ninth, tenth, or eleventh embodiment.

The multi-layered casings 10 used in the eighth to fifteenth embodiments can also be replaced with the casings 10 that are integrally formed from metal material, as shown in the sixteenth embodiment. In the first to fifteenth embodiments, one casing 10 may be selected as a layered structure composed of the first metallic layer 14, polymer membrane 15, and second metallic layer 16, while the other casing 10 may be integrally formed from metal material.

The replacement possibilities described above represent straightforward modifications that would be readily apparent to those skilled in the art based on the technical content disclosed in each embodiment.

As shown in FIG. 23, the seventeenth embodiment differs from the first embodiment primarily in that each bendable zone 11 forms the multiple thinned recesses 13 on the side opposite the chamber 40 in the third direction 96. Each thinned recess 13 extends along the second direction 94 to both sides of each casing 10, and the thinned recesses 13 formed by each casing 10 are spaced apart along the first direction 92.

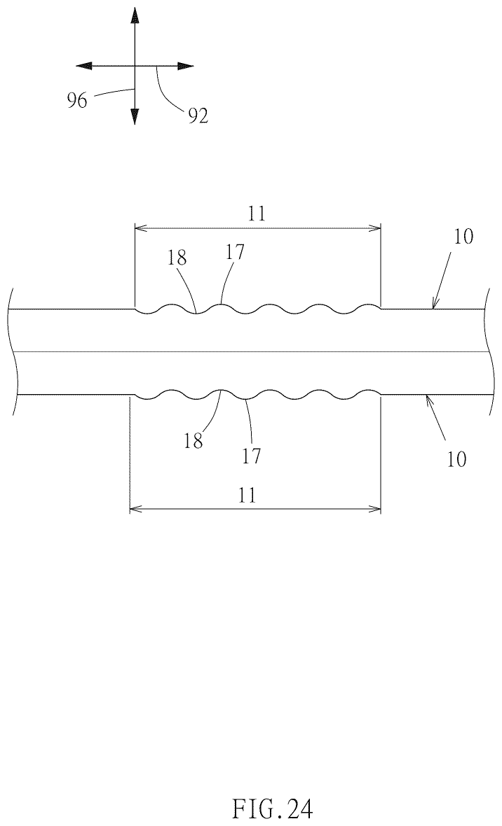

As shown in FIG. 24, the eighteenth embodiment differs from the first embodiment in that each bendable zone 11 is formed by multiple first arc segments 17 and multiple second arc segments 18, sequentially connected along the first direction 92. The first arc segments 17 and second arc segments 18 alternate along the first direction 92, forming a repeating pattern. Each first arc segment 17 protrudes toward the side opposite the chamber 40 along the second direction 94, while each second arc segment 18 is recessed toward the chamber 40 along the same direction. Both the first arc segments 17 and the second arc segments 18 extend along the third direction 96 to both sides of each casing 10, creating an undulating wave pattern in each bendable zone 11.

What is claimed is:

1. A flexible vapor chamber, comprising two casings and a wick structure, wherein each casing is a plate-like structure having a width, a length, and a thickness, with the length direction defined as a first direction, the width direction defined as a second direction, and the thickness direction defined as a third direction;
the two casings face each other along the third direction and are joined to form a perimeter seal that encloses a chamber between the casings and the perimeter seal; the chamber contains a working fluid configured to absorb and release thermal energy, wherein one of the casings is configured with multiple support pillars extending into the chamber and connecting to the opposite casing;
each casing also comprises a bendable zone and two rigid sections extending along the first direction, with the bendable zone positioned between the two rigid sections and extending to both opposite sides of the casing along the second direction, thereby enabling the casing to flex and bend along the third direction;
the chamber is primarily formed by a first space connecting two second spaces, the first space being located between the second spaces and aligned with the bendable zones in the third direction, while each second space is located between the two rigid sections in the third direction;
the wick structure is positioned in the chamber and comprises multiple elongated first capillary members, wherein each first capillary member is spaced apart along the second direction, positioned within the first space, wound into a spiral shape along the second direction and the third direction, and extends axially along the first direction into each second space, thereby directing the working fluid to flow between the second spaces through the first space along the first direction.

2. The flexible vapor chamber according to claim 1, wherein the radial cross-section of each first capillary member is either circular or rectangular.

3. The flexible vapor chamber according to claim 1, further comprising multiple bundles, each bundle being formed by twisting multiple textile fibers, wherein the axis of each bundle extends along the first direction, and each first capillary member is wound around a bundle.

4. The flexible vapor chamber according to claim 1, wherein each first capillary member includes an axial groove formed by an indentation on its radial periphery, with each axial groove extending to both ends of the first capillary member along its axis.

5. The flexible vapor chamber according to claim 1, wherein the wick structure further includes multiple transverse wicks, each transverse wick extending along the second direction and spaced apart along the first direction, and each transverse wick intersecting with each first capillary member in the third direction to form an interwoven structure.

6. The flexible vapor chamber according to claim 5, wherein the wick structure further includes multiple second capillary members and multiple intermediate wicks, with each transverse wick and each second capillary member positioned in each second space, each second space containing multiple of the transverse wicks and the multiple second capillary members;
each second capillary member is spirally wound in the second direction and the third direction, with its axis extending along the first direction, allowing the second capillary member to guide the working fluid to flow between the first space and the corresponding second space along the first direction;
each second capillary member is located between two first capillary members and is spaced apart from two adjacent first capillary members along the second direction; each transverse wick intersects with the first capillary members and the second capillary members in the third direction to form an interwoven structure;
the intermediate wicks are arranged in an array pattern within the first space, with each intermediate wick extending along the second direction and intersecting with two adjacent first capillary members in the second direction and the third direction to form an interwoven structure.

7. The flexible vapor chamber according to claim 1, wherein the wick structure further includes two wicking grids, each wicking grid being located within a respective second space, each wicking grid formed by multiple intersecting and interwoven grid wicks, with multiple first capillary members bundled together along the second direction, and each first capillary member connected to the corresponding wicking grid.

8. The flexible vapor chamber according to claim 5, wherein the multiple first capillary members are bundled together along the second direction.

9. The flexible vapor chamber according to claim 1, wherein each casing is primarily composed of a layered structure consisting of a first metallic layer, a flexible polymer membrane, and a second metallic layer, with each polymer membrane sandwiched between the first metallic layer and the second metallic layer, and wherein each casing forms a thinned recess on the side opposite the chamber in the third direction, causing a reduced thickness that forms each bendable zone.

10. A flexible vapor chamber, comprising two casings and a wick structure, wherein each casing is a plate-like structure having a width, a length, and a thickness, with the length direction defined as a first direction, the width direction defined as a second direction, and the thickness direction defined as a third direction;
the two casings face each other along the third direction and are joined to form a perimeter seal that encloses a chamber between the casings and the perimeter seal; the chamber contains a working fluid configured to absorb and release thermal energy, wherein one of the casings is configured with multiple support pillars extending into the chamber and connecting to the opposite casing;
each casing also comprises a bendable zone and two rigid sections extending along the first direction, with the bendable zone positioned between the two rigid sections and extending to both opposite sides of the casing along the second direction, thereby enabling the casing to flex and bend along the third direction;
the chamber is primarily formed by a first space connecting two second spaces, the first space being located between the second spaces and aligned with the bendable zones in the third direction, while each second space is located between the two rigid sections in the third direction;
the wick structure is positioned in the chamber and comprises multiple elongated first capillary members, wherein each first capillary member is spaced apart along the second direction, positioned within the first space, formed by twisting multiple strands, and extends axially along the first direction into each second space, with each strand wound into a spiral shape along the second direction and the third direction, thereby directing the working fluid to flow between the second spaces through the first space along the first direction.

11. The flexible vapor chamber according to claim 10, wherein the radial cross-section of each strand is either circular or rectangular.

12. The flexible vapor chamber according to claim 10, further comprising multiple bundles, each bundle being formed by twisting multiple textile fibers, wherein the axis of each bundle extends along the first direction, and the multiple strands and the multiple bundles are twisted together to form each first capillary member.

13. The flexible vapor chamber according to claim 10, further comprising multiple bundles, each bundle being formed by twisting multiple textile fibers, wherein the axis of each bundle extends along the first direction, and multiple strands are wound around each bundle to form each first capillary member.

14. The flexible vapor chamber according to claim 10, wherein each strand includes a strand groove formed by an indentation along its radial periphery, with each strand groove extending to both ends of the strand along its axis.

15. The flexible vapor chamber according to claim 10, wherein the wick structure further includes multiple transverse wicks, each transverse wick extending along the second direction and spaced apart along the first direction, and each transverse wick intersecting with each first capillary member in the third direction to form an interwoven structure.

16. The flexible vapor chamber according to claim 15, wherein the wick structure further includes multiple second capillary members and multiple intermediate wicks, with each transverse wick and each second capillary member positioned in each second space, each second space containing multiple of the transverse wicks and the multiple second capillary members;
each second capillary member is spirally wound in the second direction and the third direction, with its axis extending along the first direction, allowing the second capillary member to guide the working fluid to flow between the first space and the corresponding second space along the first direction;
each second capillary member is located between two first capillary members and is spaced apart from two adjacent first capillary members along the second direction; each transverse wick intersects with the first capillary members and the second capillary members in the third direction to form an interwoven structure;
the intermediate wicks are arranged in an array pattern within the first space, with each intermediate wick extending along the second direction and intersecting with two adjacent first capillary members in the second direction and the third direction to form an interwoven structure.

17. The flexible vapor chamber according to claim 10, wherein the wick structure further includes two wicking grids, each wicking grid being located within a respective second space, each wicking grid formed by multiple intersecting and interwoven grid wicks, with multiple first capillary members bundled together along the second direction, and each first capillary member connected to the corresponding wicking grid.

18. The flexible vapor chamber according to claim 15, wherein the multiple first capillary members are bundled together along the second direction.

19. The flexible vapor chamber according to claim 10, wherein each casing is primarily composed of a layered structure consisting of a first metallic layer, a flexible polymer membrane, and a second metallic layer, with each polymer membrane sandwiched between the first metallic layer and the second metallic layer, and wherein each casing forms a thinned recess on the side opposite the chamber in the third direction, causing a reduced thickness that forms each bendable zone.
